(19) United States
(12) Patent Application Publication
(10) Pub. No.: US 2024/0335954 A1
(43) Pub. Date: Oct. 10, 2024

(54) END EFFECTOR PAD DESIGN FOR BOWED WAFERS

(71) Applicant: Lam Research Corporation, Fremont, CA (US)

(72) Inventors: Melinda P. Chen, San Jose, CA (US); Eric Bramwell Britcher, San Jose, CA (US); Charles N. Ditmore, Oakland, CA (US); Ryan Louis Mack, San Jose, CA (US); Gregory Alan Vaughn, San Jose, CA (US)

(21) Appl. No.: 18/698,717

(22) PCT Filed: Oct. 5, 2022
(86) PCT No.: PCT/US2022/045712

§ 371 Date: Apr. 4, 2024

Related U.S. Application Data
(60) Provisional application No. 63/262,240, filed on Oct. 7, 2021.

(51) Int. Cl. B25J 15/00; B25J 11/00

(52) U.S. Cl. CPC B25J 15/0014; B25J 11/0095

(57) ABSTRACT

End effector pads are provided that may be used to secure substrates to an end effector on a wafer handling robot. An end effector may have a plurality of end effector pads. Each of the end effector pads may have a thin diaphragm that allows a peripheral ring of the pad to tilt slightly to allow the ring to seal against a bottom surface of a bowed substrate. A vacuum may be used to pull down the substrate against a hard-stop on each end effector pad and hold the substrate more securely. The hard-stop may be used to consistently locate the z-position of the bottom surface of the substrate relative to the end effector.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

In semiconductor wafer processing tools, wafer handling robots with end effectors may be used to transfer substrates between different locations within a tool, such as processing stations, front-opening universal pods (FOUPs), aligners, load locks, etc. In some types of end effector, when a substrate is handled by a wafer handling robot, the substrate sits on end effector pads located on the end effector. The end effector pads may be used to secure the substrate to the wafer handling robot through the use of vacuum and frictional force. If the substrate is not properly secured to the wafer handling robot, the substrate may slip when being transferred. A substrate slipping may create a variety of risks such as breaking substrates, crashing substrates, misalignment of substrates in processing stations, and other tool errors.

### SUMMARY

In some implementations, an end effector pad for supporting a substrate may be provided that includes a center portion extending along a longitudinal axis, a ring extending around, and radially offset from, the center portion, a diaphragm connecting the ring with the center portion, and one or more hard-stop structures. A surface of the ring that is furthest from the center portion and offset from the diaphragm along the longitudinal axis may define a first reference plane that is perpendicular to the longitudinal axis and one or more hard-stop surfaces of the one or more hard-stop structures that are furthest from the center portion may define a second reference plane that is also perpendicular to the longitudinal axis. The second reference plane may be between the diaphragm and the first reference plane and the center portion may have one or more passages extending therethrough.

In some implementations of the end effector pad, the center portion, the ring, and the diaphragm may form a contiguous structure made of a material having a modulus of elasticity of at least 0.8 GPa.

In some implementations of the end effector pad, the diaphragm may include at least three rib regions in which the thickness of the diaphragm is thicker than in regions of the diaphragm in between the rib regions, each rib region extending from the center portion to the ring.

In some implementations of the end effector pad, regions of the diaphragm between the rib regions may have a thickness between 0.003 inches and 0.005 inches.

In some implementations of the end effector pad, regions of the diaphragm between the rib regions may have a thickness between 0.005 inches and 0.007 inches.

In some implementations of the end effector pad, regions of the diaphragm between the rib regions may have a thickness between 0.007 inches and 0.009 inches.

In some implementations of the end effector pad, each rib region may have a surface of that rib region that is closest to the first reference plane that defines a third reference plane that is perpendicular to the longitudinal axis. The second reference plane may be between the third reference plane and the second reference plane.

In some implementations of the end effector pad, at least a portion of each rib region may have a width in a direction transverse to a radial axis perpendicular to the longitudinal axis that is between 0.02 inches and 0.04 inches.

In some implementations of the end effector pad, the diaphragm may have four rib regions.

In some implementations of the end effector pad, the intersection of the ring and the first reference plane may form a contact region with a radial width that is <5% than a diameter of the ring.

In some implementations of the end effector pad, the one or more hard-stop surfaces may have a radial width that is less than 5% of the maximum dimension of the center portion in a direction perpendicular to the longitudinal axis.

In some implementations of the end effector pad, the one or more hard-stop structures may be a ring-like structure having a diameter the same diameter as the center portion.

In some implementations of the end effector pad, the one or more hard-stop structures may be a single structure that provides a single hard-stop surface.

In some implementations of the end effector pad, the one or more hard-stop structures may be a plurality of arcuate wall segments arranged in a circular array around a center axis of the center portion.

In some implementations of the end effector pad, the diaphragm may have at least three rib regions in which the thickness of the diaphragm is thicker than in regions of the diaphragm in between the rib regions. Each rib region may extend from the center portion to the ring and each arcuate wall segment may be positioned at an interior end of a corresponding one of the rib regions.

In some implementations of the end effector pad, at least a portion of the passage may have a hexagonal cross-sectional shape.

In some implementations of the end effector pad, each corner of the hexagonal cross-sectional shape may have an arcuate notch.

In some implementations of the end effector pad, at least a portion of an exterior surface of the center portion may be threaded.

In some implementations of the end effector pad, the end effector pad may be made of plastic.

In some implementations of the end effector pad, the plastic may be a conductive electrostatic discharge-rated plastic.

In some implementations of the end effector pad, the plastic may be a polybenzimidazole (PBI).

In some implementations of the end effector pad, the plastic may be a carbon-filled polyetheretherketone (PEEK).

In some implementations of the end effector pad, the ring may have a diameter between 0.20 inches and 1.50 inches.

In some implementations of the end effector pad, the ring may have a diameter between 0.40 inches and 0.80 inches.

In some implementations, a kit for use on a wafer handling robot may be provided. The kit having least three end effector pads such as are described above.

In some implementations of the kit, at least a portion of the passage of each of the end effector pads may have a hexagonal cross-sectional shape.

In some implementations of the kit, the kit further may further include a hex wrench configured to fit in the portion of the passage with the hexagonal cross-sectional shape.

### BRIEF DESCRIPTION OF DRAWINGS

FIGS. 1-1 and 1-2 show an example end effector with example end effector pads.

FIG. 2 shows a top view of an example end effector pad.

FIG. 3 shows a perspective view of another example end effector pad.

FIG. 4-1 and FIG. 4-2 show a cross-sectional view of an example end effector pad.

FIG. 5 shows a top view of another example end effector pad.

FIG. 6 shows a kit with three example end effector pads and an example hexagonal-shaped wrench.

FIG. 7 shows a cross-sectional view of an example end effector pad on an example end effector.

FIGS. 8-1 and 8-2 show an example bowed substrate on an end effector before and after vacuum is pulled.

### DETAILED DESCRIPTION

In the following description, numerous specific details are set forth to provide a thorough understanding of the presented embodiments. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments.

During semiconductor wafer processing, substrates, e.g., semiconductor wafers, are transferred within a semiconductor processing tool by wafer handling robots. Wafer handling robots may have an end effector used to hold the substrate. Some end effectors use end effector pads that contact the underside of the wafer and that hold the wafer in place through friction. When a substrate supported by such end effector pads is moved by a wafer handling robot, the substrate is subjected to accelerations which may cause the substrate to slip relative to the end effector. Slippage of a substrate off a wafer handling robot may cause several issues, including dropping wafers, crashing wafers, misalignment of wafers, and other tool errors.

Some end effector pads may secure a substrate to the wafer handling robot by the use of frictional force that is amplified by vacuum force, e.g., the end effector pads may be configured to apply a vacuum to the underside of the substrate so as to create a pressure differential that causes the substrate to be clamped against the end effector pad with more force than is applied by gravity alone, thereby increasing the friction force developed between the end effector pad and the substrate. When using such a vacuum-assist feature, the end effector pads create a seal with a bottom surface of the substrate. Once a seal is created, a vacuum pump may be used to pull vacuum through the end effector pad.

However, certain semiconductor processes have been found to cause substrates to bow, e.g., develop a slight curvature. The amount of bow can vary from substrate to substrate, and it has been observed that the bow that is observed in substrates is becoming more pronounced in newer semiconductor manufacturing processes. For example, in some processes, the substrates processed may develop a bow with a planarity of 1 mm or more, e.g., if the bowed substrate is placed concave-side down on a flat surface, the highest point of the wafer from the flat surface may be 1 mm higher or more than the nominal thickness of the substrate. Further, the direction of the bow can vary, e.g., some substrates have a bow that is concave-up and other substrates concave-down, so direction of slope can reverse depending on the orientation (or wafers may be flipped upside down in between some processing operations, resulting in the bow direction reversing). The sloping underside of bowed substrates can result in i) effector pads, which are typically arranged so as to evenly contact a planar surface, not contacting the underside with enough surface area to produce desired friction forces that act to hold the wafer in place during movement of the end effector and ii) end effector pads with vacuum-assist not being able to form a seal to allow an applied vacuum to develop vacuum clamping forces.

Some existing elastomeric end effector pads could conform to the slight amount of slope in the underside of a bowed wafer, but end effector pads made of softer, more compliant elastomeric material suitable for use in suction cups or similar devices would have material incompatibilities with the substrates, generally have poor resistance to high temperatures (for example, the end effector pads described herein are suitable for use at temperatures of 250° C. or higher, whereas the select few elastomeric materials that are capable of surviving such temperatures may become tacky or sticky under such conditions and make it difficult to remove the wafer from the pad), and could potentially introduce an element of compliance that would result in less precise substrate positioning due to their lower elastic modulus (for example, having greater variability in vertical positioning of the wafer supported thereby), which could prove problematic given the tolerances and clearance zones that need to be available in wafer handling systems. Embodiments of the present disclosure describe a superior solution to elastomeric end effector pads. According to some embodiments, an end effector pad made of a single piece of material, e.g., as a single contiguous structure, with a relatively high tensile modulus, e.g., ≥0.8 GPa, and a relatively high flexural modulus, e.g., ≥0.9 GPa, is disclosed. The end effector pad is generally rigid except for the ability to flex slightly to as to conform to the slope of the underside of a bowed substrate and thereby have full contact with the underside of the bowed substrate while providing a rigid structure that predictably locates the wafer in space relative to the end effector, does not risk adhering or sticking to the wafer, and is capable of withstanding elevated temperatures that may be encountered by the pad when interacting with hot wafers.

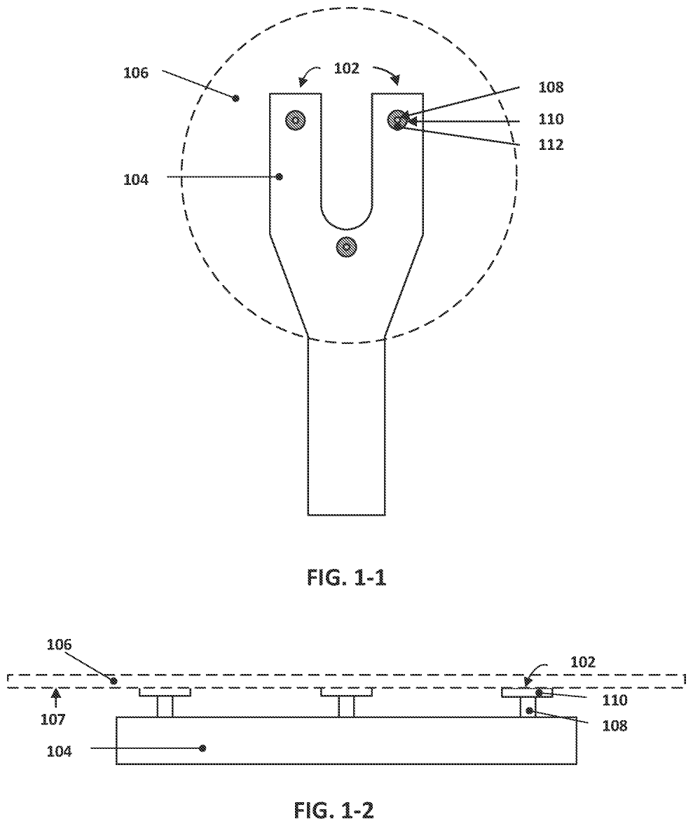

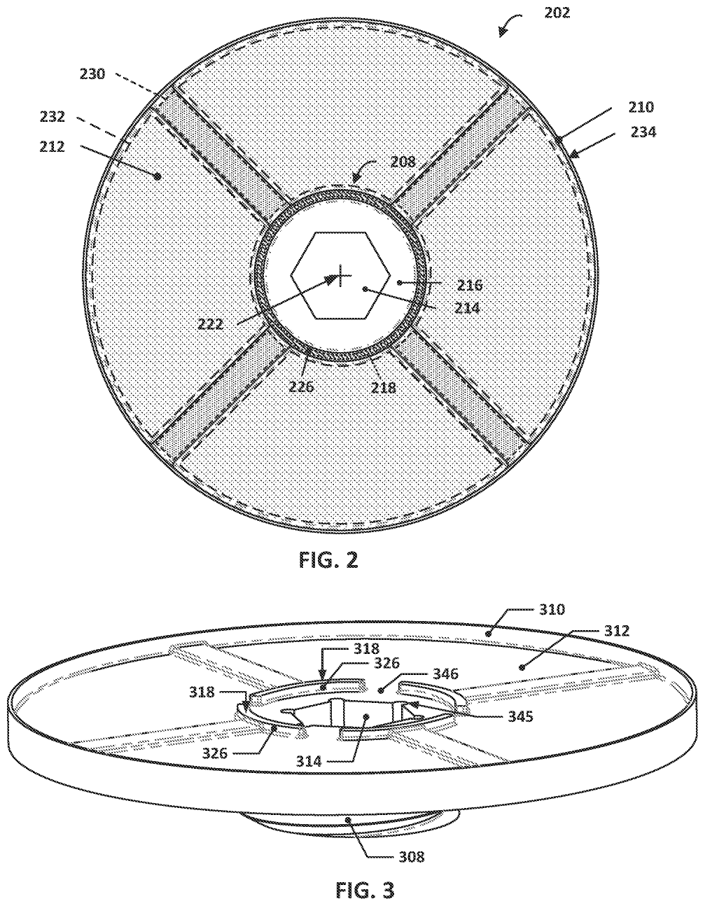

FIGS. 1-1 and 1-2 show two views of an example of end effector pads 102 on an end effector 104 according to some embodiments of the present disclosure. FIG. 1-1 shows a top view of three end effector pads 102 on the end effector 104 with the outline of an example substrate 106 over the end effector 104. FIG. 1-2 shows a side view of the end effector 104 with three end effector pads 102 and the substrate 106. In FIG. 1-2, the middle end effector pad 102 is deeper than the two outside end effector pads 102, which may have the same depth. The end effector pads may also be referred to herein simply as “pads.” Each pad has a center portion 108, a diaphragm 112, and a ring 110.

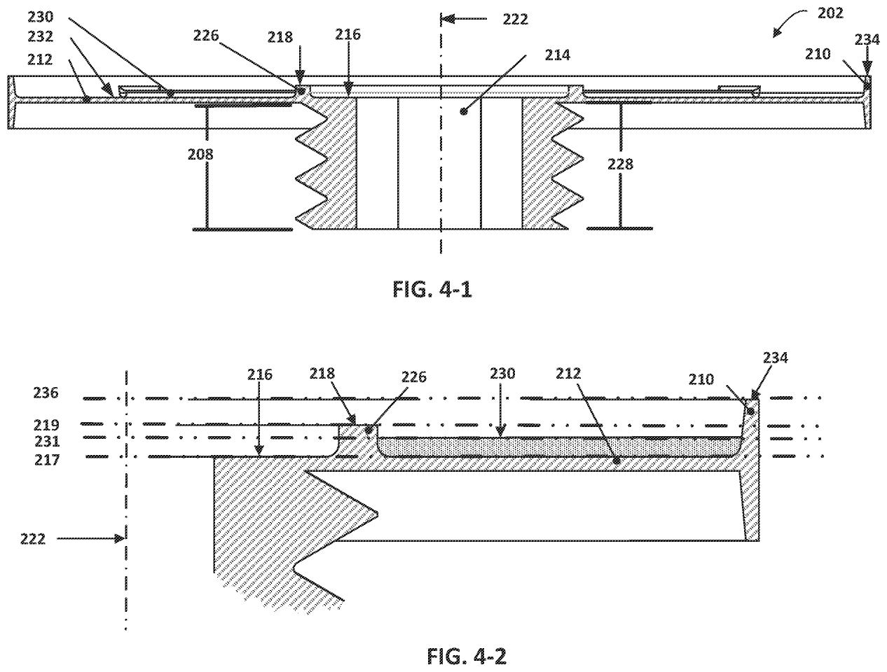

An end effector 104 may have a plurality of pads 102. In the example shown, there are three pads 102. Each of the end effector pads 102 may work together to secure the substrate 106 to the end effector 104. The rings 110 of each pad 102 come in contact with a bottom surface 107 of the substrate 106 when the substrate is placed on the end effector 104. Each pad 102 may generate its own friction force in a localized area of the bottom surface 107. Each pad 102 may also be connected with a vacuum source such that a vacuum can be drawn on the substrate via each pad 102 so as to create a pressure differential that acts to bias the substrate towards the pads 102. The friction forces exerted on the substrate by the pads 102, in combination with the vacuum clamping of the substrate to the pads 102, may provide a clamping force that acts to resist any lateral loading of the substrate 106, e.g., such as inertial loads that may be generated when the end effector is moved in the horizontal plane at high speed, that might result in slippage of the substrate relative to the end effector. FIG. 2 shows a top view of an example end effector pad 202 according to some embodiments of the present disclosure. FIGS. 4-1 and 4-2 show two cross sectional views of the example end effector pad 202. FIG. 4-1 is a cross section of the entire pad 202 and FIG. 4-2 shows a zoomed-in cross-sectional view of part of the pad. The end effector pad 202 has a center portion 208, a ring 210, and a diaphragm 212 that connects the ring 210 to the center portion 208. The center portion 208 attaches the pad 202 to an end effector (not shown). Connected to the center portion 208 is the diaphragm 212. The ring 210 is on the outside of the pad 202 and is connected to the center portion 208 by the diaphragm 212.

As shown in FIGS. 2, 4-1, and 4-2, the center portion 208 has a face 216 and a passage 214. The face 216 defines a face reference plane 217. The face reference plane 217 is substantially perpendicular to a center axis 222 that extends along the longitudinal direction of the center portion 208, e.g., along a longitudinal axis. The passage 214, as shown in FIG. 4-1, may extend along the center axis 222 through the center portion 208 and the face 216 of the center portion 208. In some embodiments, the passage 214 is a single passage. In some embodiments, there may be one or more passages.

FIG. 2 shows the passage 214 from a top view. In the embodiment shown, the passage 214 may have a cross-sectional shape that allows a wrench or other driver tool, e.g., a screwdriver, to be used to install or remove the pad 202 from an end effector (not shown). In this embodiment, the passage 214 has a cross-sectional shape that is hexagonal to allow it to be interfaced with a hex key or Allen wrench. The size and shape of the passage cross-sectional profile may change depending on the size and type of tool used. Other examples of shapes for the passage may include a six-point-star shape for installation with a hexalobular or star-drive wrench, a cross or “+” shape for installation with a Phillips-head screwdriver, or a long, thin rectangle for installation with a flat head screwdriver.

The center portion 208 may have one or more hard-stop structures 226 that extend from the face 216 or that provide the face 216. The hard-stop structures 226 may be used to define a z-location of a substrate when the substrate is secured to an end effector. When a substrate is placed on a pad 202, generally, the substrate first comes into contact with the ring 210, which is discussed further below. A vacuum pump may be used to pull a vacuum pressure through the passage 214. The vacuum may pull the substrate downward against the pad 202, causing the diaphragm 212 to flex and allow the ring 210 (and substrate) to move downward toward a top surface of an end effector. The one or more hard-stop structures 226 of center portion 208 act to limit the amount of downward travel that the substrate may undergo and may define the height of the bottom surface of the substrate relative to the end effector. Each hard-stop structure 226 may have a hard-stop surface 218. In the depicted example, the one or more hard-stop structures are provided by a single annular wall that has an annular hard-stop surface 218. The hard-stop surface 218 is a surface that makes contact with the substrate when the substrate is pulled down against the pad 202 and that limits the vertical travel of the substrate. The hard-stop surfaces 218 of the one or more hard-stop structures 226 define a hard-stop reference plane 219 as shown in FIG. 4-2. The hard-stop reference plane 219, which may also be referred to herein as a second reference plane, is substantially perpendicular to the center axis 222 and is a defined distance from the face reference plane 217 of the center portion 208 along the center axis 222. By having a defined distance between the hard-stop reference plane 219 and the face reference plane 217 of the center portion 208, a substrate placed on the end effector pad 202 will always be a known distance away from a top surface of an end effector. In some embodiments, the hard-stop reference plane 219 may be coplanar with the face reference plane 217. In some alternate embodiments, however, the hard-stop reference plane 219 may be closer to a ring reference plane 236 (as shown in FIG. 4-2) that is defined by a surface of the ring that contacts the substrate when the pad is used to support the substrate; the ring reference plane may also be referred to herein as a first reference plane. The application of vacuum to the region between the pad and a substrate placed thereupon may act to pull down the substrate to the hard-stop structure 226 and thus to a repeatable height above the end effector. With a wafer handling robot transferring substrates to locations with small height clearance, e.g., less than 10 mm, the ability to consistently secure substrates at a predetermined height above the end effector allows more of such a height clearance range to be used to accommodate potential variance in other aspects of the wafer handling system, such as wafer bow, end effector placement accuracy, assembly tolerances, etc. In particular, since most substrate handling systems are designed with clearance envelopes and tolerances that assume a planar substrate, the presence of a bowed substrate in such systems may pose particular challenges since a bowed substrate may, in some cases, be twice as “thick” than a planar substrate due to the bow. For example, the outer edge of such a substrate may be displaced upward or downward by some amount due to the bow, while the center of the substrate may be displaced in the opposite direction by some amount. The difference between the maximum or minimum elevation at the center of the bowed wafer and the edges of the bowed substrate may represent a “thickness” of the substrate that is significantly thicker than the planar thickness of the substrate (for example, a typical semiconductor wafer may be approximately 0.750 mm thick, and such a substrate that is bowed may be bowed by an amount that is greater than the planar thickness of the substrate.) This additional thickness may reduce the available clearances that have been designed into the substrate handling system, thereby reducing the operating margins that are available to the system. By using a hard-stop structure, the end effector pads in some embodiments of the present disclosure may reduce or minimize the amount of vertical placement uncertainty that may exist for substrates supported thereby, thus potentially offsetting at least some of the operating margins that are lost due to bowing of the substrate.

As shown in FIGS. 2 and 4-1 and 4-2, in some embodiments, the center portion 208 may have a single hard-stop structure 226. For example, the hard-stop structure may simply be a ring-shaped hard-stop structure 226 around the center axis 222. In another example, the single hard-stop structure 226 may be the top area of the center portion 208 and may have hard-stop surface 218 be the face 216 of the center portion 208 (e.g., the center portion 208 may extend past the diaphragm 212).

In other implementations, as shown in FIG. 3, a plurality of hard-stop structures 326 may be provided that are in the form of arcuate wall segments that are arranged in a circular array so as to encircle the passage 314. In such an implementation, channels 346 may be provided in between each such hard-stop structure 326 to allow for fluid flow between the hard-stop structures 326 so that a vacuum can be reliably drawn across the entire surface area of the end effector pad. The substrate may, when vacuum clamped to the pad, come into contact with arc-shaped hard-stop surfaces 318 due to flexure of the diaphragm 312 and downward displacement of the ring 310. In some implementations, the corners of the cross-sectional shape of the passage 314 may have circular or arcuate notches 345 that may be provided to reduce stress concentrations at such locations, reduce the risk of damage to the pad during installation, and ease manufacturability; such features may be used in any of the implementations discussed herein.

In some embodiments, there may be two or more hard-stop structures 226. In the embodiment shown in FIG. 3 there are four hard-stop structures 326 with four channels 346. In some implementations, each hard-stop surface 318 of each of the hard-stop structures 326 may be thin relative to the diameter of the ring 310 to minimize the contact between the pad and a substrate. For example, in some implementations, the radial width of a hard-stop surface 318 may be less than 5% of the maximum diameter of the center portion. Such radial widths may be used in the hard-stop structures shown in other implementations discussed above as well.

Returning to FIGS. 4-1 and 4-2, the elevation (with respect to the orientations of FIGS. 4-1 and 4-2) of hard-stop surfaces 218 (co-planar with line 219 in FIG. 4-2) is between the elevations of a ring contact surface 234 (co-planar with line 236 in FIG. 4-2) of the ring 210 and the top surface of the diaphragm 212 (co-planar with line 217 in FIG. 4-2). This allows the ring 210 to make initial contact with the substrate and allows the pad 202 to pull vacuum between the substrate and the pad. In some embodiments, the hard-stop surface 218 is above the highest surface of the diaphragm 212. This prevents any contact between the diaphragm 212 and the substrate, thereby reducing particle generation due to contact between the substrate and the diaphragm.

The flexibility of the diaphragm 212 allows the ring 210 to pivot slightly about an axis that is perpendicular to the center axis 222 and relative to the center portion 208. In some embodiments, the diaphragm 212 may have rib regions 230 and webs 232 in between the rib regions 230. The rib regions 230 are stiffer than the webs 232 and, generally speaking, serve as radial stiffeners that prevent the ring from collapsing radially inward when subjected to vacuum during the vacuum clamping of the substrate. The webs 232 are more compliant than the rib regions 230 and enable the diaphragm 212 to be sufficiently flexible that the diaphragm 212 can flex so as to allow the ring to tilt slightly so as to conform to the underside of a bowed substrate.

The diaphragm 212 may have three or more rib regions 230 according to some embodiments. Shown in the top view in FIG. 2, the pad 202 has four rib regions 230. Generally, the rib regions 230 have a smaller surface area perpendicular to the center axis 222 than the webs 232. For example, the rib regions 230 may have a width between 0.02 inches and 0.04 inches. The web 232, depending on the material, may have a thickness of between 0.003 inches and 0.005 inches. In some embodiments, the web 232 may have a thickness between 0.005 and 0.007 inches. In still some other embodiments, the web may have a thickness between 0.007 inches and 0.009 inches. The rib regions 230, in contrast, may have a thickness between 0.008 inches and 0.015 inches. It will be understood that the term “between,” as used herein to refer to a numeric range, refers to any value between two indicated values or equal to either of those two values (the range is not exclusive of the endpoints of the range). A surface of the rib region 230 that is generally closest to the ring contact surface 234 along the center axis 222 of the center portion 208 defines a rib reference plane 231 (as shown in FIG. 4-2). In some embodiments, the hard-stop reference plane 219 may be interposed between the rib reference plane 231 and the ring contact surface 234. By having the rib reference plane 231 further from the ring contact surface 234 than the hard-stop reference plane 219, the potential contact area between the pad 202 and a substrate is reduced to include only the one or more hard-stop surfaces 218 and the ring contact surface 234, thereby avoiding contact between the substrate and the diaphragm 212. Since the material of the end effector pad 202 is relatively rigid, the diaphragm has sufficient thickness and stiffness to avoid flexing into contact with the substrate when under vacuum loading.

As noted earlier, the ring 210 extends around the center portion 208 and is connected to the center portion by the diaphragm 212. As also noted, the ring 210 has a ring contact surface 234. The ring contact surface 234 defines a ring reference plane 236. When the pad 202 has no outside forces acting on it, e.g., the weight of a substrate, the ring reference plane 236 is further from the center portion 208 along the center axis 222 of the center portion 208 than the hard-stop reference plane 219. The ring 210 may have a diameter of between 0.20 inches and 1.50 inches. In some embodiments, the diameter of the ring 210 may be between 0.4 inches and 0.8 inches. Rings 210 of this diameter offer a good balance of increased clamping force with and reduced contact area between the pad and the substrate. Shown in the top view of FIG. 2, the radial thickness or width of the ring contact surface 234 is thin relative to the diameter of the ring 210. In some embodiments, the radial thickness of the ring contact surface 234 is less than 5% of the outer diameter of the ring 210. For example, for a ring with a diameter of 0.6 inches, the radial thickness of the ring contact surface 234 may be less than 0.03 inches. In some embodiments, the radial thickness may be between 0.003 and 0.010 inches. The ring contact surface 234 is kept deliberately small, e.g., less than 0.015 square inches, to reduce or minimize the contact area made between the pad 202 and a substrate. Minimal or reduced contact between the pad 202 and a substrate helps prevent inadvertent adhesion of the pad to the substrate after the vacuum clamping is released and reduces the number of particles that may potentially be generated by contact of the pad with the substrate.

Generally, the ring reference plane 236 may be perpendicular to the center axis 222, e.g., the ring contact surface 234 may be parallel to a surface of an end effector. When a substrate is placed on the pad 202, the substrate may come into contact with the ring contact surface 234. When a bowed substrate is placed on the pad 202, the substrate will usually first contact either the outermost or innermost portions of the edge of the ring 210 (relative to the center axis of the substrate) due to the curvature/slope of the substrate (if the convex side of the substrate is facing away from the pads, then the substrate will likely first contact the portion of the pad furthest from the substrate center axis, while if the concave side of the substrate is facing away from the pads, then the substrate will likely first contact the portion of the pad closest to the substrate center axis). The weight of the substrate may exert a force on the ring 210 that causes a torque to develop in the diaphragm 212 and, due to its thinness, causes the diaphragm to flex slightly, allowing the rest of the ring to tilt so as to contact or move to a position more proximate to the bottom surface of the substrate. The ring 210 may not actually be in full contact with the substrate after this gravity-assisted tilting, but may nonetheless be close enough that the flow conductance through whatever gap may exist between the pad and the substrate is low enough that the vacuum-assist is still able to maintain a vacuum in between the pad and the substrate that, in turn, causes the substrate to be pulled towards the pad even more and make the ring contact surface 234 fully contact the wafer. The vacuum-assist thus pulls the substrate further down so that the ring reference plane 236 moves closer to the center portion 208. In some cases, the ring reference plane 236 may become nominally coplanar with the hard-stop reference plane 219 after the vacuum-assist is applied to the substrate.

The pad 202 may be used in processing chambers that may exceed temperatures of up to 250° C. Materials, such as a rigid material, that is capable of withstanding high temperatures, e.g., 250° C., and providing dimensional certainty as to where the substrate is located would be desirable. A material having a modulus of elasticity of at least 0.8 GPa, for example, a modulus between 0.8 GPa and 1.65 GPa, may provide sufficient rigidity to allow for accurate and predictable wafer placement while still providing sufficient flexibility to allow the diaphragm and ring to shift to conform to the sloped underside of a bowed substrate. The use of a rigid material within the above modulus range allows the pad 202 to have a stiff center portion 208 designed to provide dimensional certainty with regard to the vertical placement of the substrate relative to the end effector and a thin web 232 that allows the ring 210 flexibility to adapt to bow of a substrate while still remaining stiff enough radially to avoid puckering or crumpling of the pad under vacuum loading. Further, such materials may be better able to withstand high-temperature processes. In some embodiments, the rigid material may be a rigid plastic. In some embodiments, such a plastic may be an electrically conductive plastic, e.g., conductive electrostatic-discharge-rated plastic. In a preferred embodiment, the material may be carbon-filled polyetheretherketone (PEEK) plastic. In another embodiment, the material may be made of a polybenzimidazole (PBI) fiber.

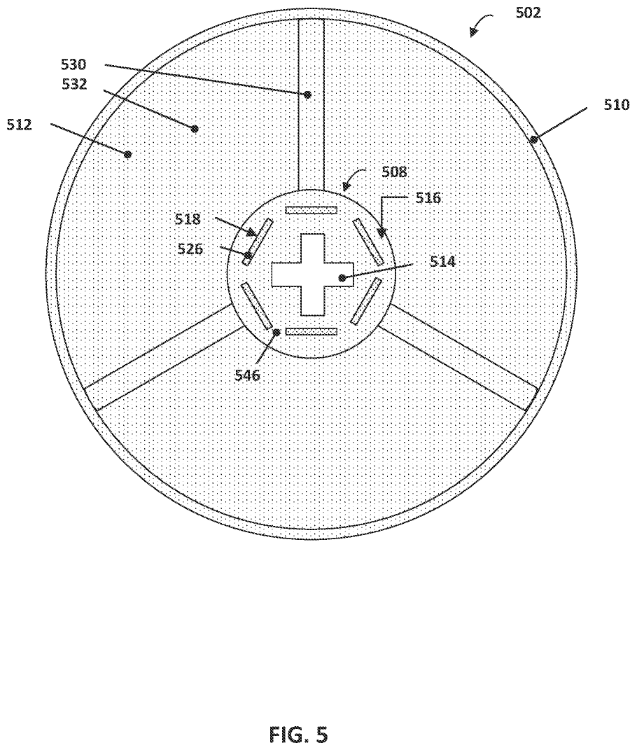

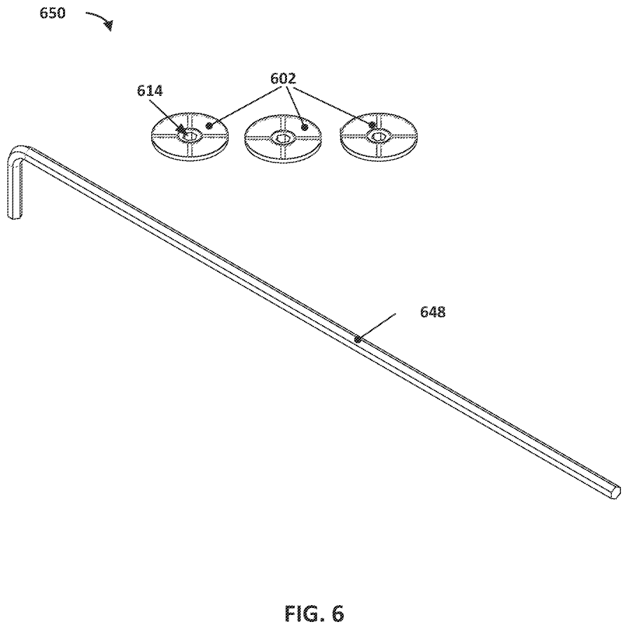

FIG. 5 is another example of an end effector pad 502. The end effector pad 502 has a center portion 508, a diaphragm 512, and a ring 510. The center portion 508 has a passage 514, a face 516, and multiple hard-stop structures 526. In this embodiment, the passage 514 has a cross-section that is cross-shaped to allow it to be interfaced with a Phillips-head screwdriver. There are six hard-stop structures 526 and six channels 546. Each hard-stop surface 518 has a radial width that is <5% of the maximum radial dimension of the center portion 508. As discussed earlier, the channels 546 provide fluid flow paths that allow the vacuum to be evenly applied across the entire area of the diaphragm 512 to pull against a substrate when the substrate is resting on a hard-stop surface 518 of each of the six hard-stop structures 526. The diaphragm 512 has rib regions 530 and webs 532. In the embodiment shown, the diaphragm 512 has three rib regions 530 which may help reduce distortion or crumpling of the webs 532 and the ring 510.

Shown in FIG. 6 is a kit 650. The kit 650 has three end effector pads 602, although other implementations of the kit may have three or more end effector pads 602. In some embodiments of the kit 650, each of the three end effector pads 602 may have a hexagonal passage 614. In some embodiments, where the end effector pads 602 have a hexagonal shaped passage 614, the kit 650 may also have a hex wrench 648 configured to snugly fit in the hexagonal passage 614 to allow the pads 602 to be installed in threaded holes provided in an end effector.

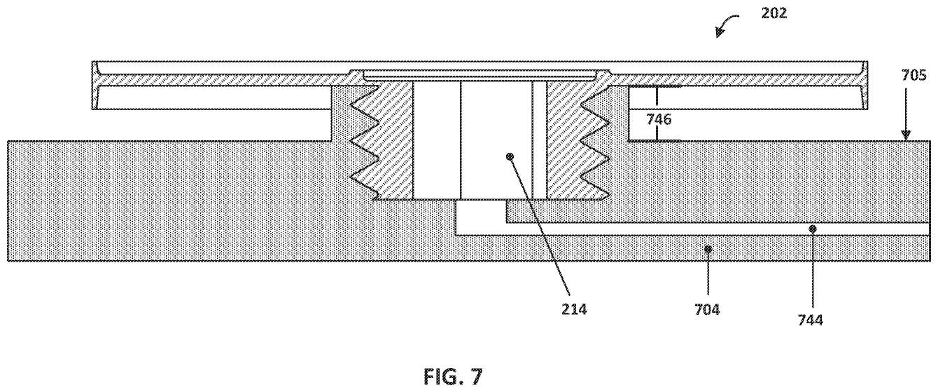

As discussed earlier, a vacuum-assist feature may be used to draw a vacuum on the volumes trapped between each of the end effector pads and the substrate. FIG. 7 shows a cross-section of the example end effector pad 202 in an example end effector 704. The pad 202 attaches to a top surface 705 of the end effector 704 by way of a threaded outer surface of the center portion 208. The threaded outer surface 228 (see FIG. 4-1) may be used to secure the pad 202 into the end effector 704. In the example in FIG. 7, the top surface 705 of the end effector 704 has raised bosses 746 with threaded holes for the threaded outer surface 228 to screw into. As shown in FIG. 7, the end effector 704 may have a vacuum passage 744 that connects to the passage 214 in the pad 202. A vacuum may be pulled on the underside of a substrate via the vacuum passage 744 and the passage 714 when the substrate is placed on the pad 202. A pump (not shown) may be connected to the passage 214 through the vacuum passage 744 and be used to pull the vacuum when the substrate is placed on the end effector pad 202.

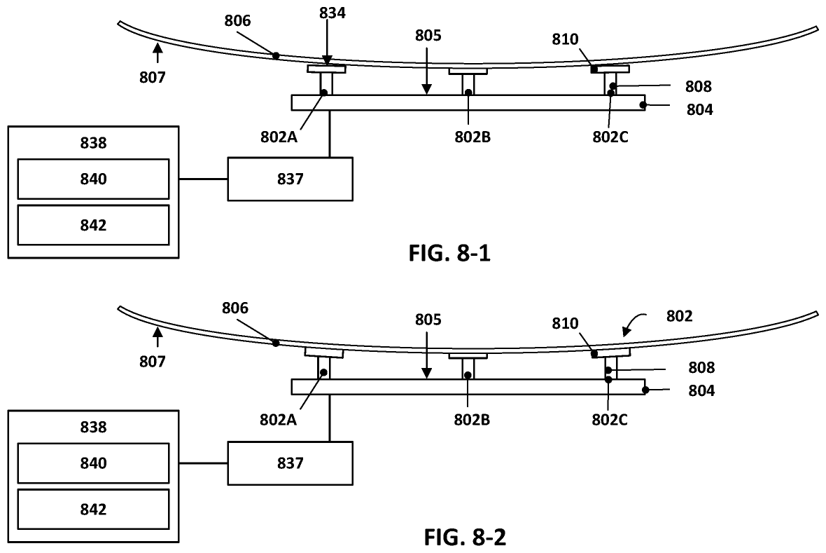

As noted earlier, when a substrate is placed on an end effector, end effector pads may be used to secure the substrate to the end effector 804. Shown in FIGS. 8-1 and 8-2 is an example of a bowed substrate 806 being secured to an end effector 804 by three end effector pads 802: a left end effector pad 802A, a middle end effector pad 802B, and a right end effector pad 802C. FIG. 8-1 shows the bowed substrate 806 initially in contact with each of the three end effector pads 802 before vacuum is applied. FIG. 8-2 shows the substrate 806 and end effector pads 802 after vacuum is applied. FIG. 8-1 and FIG. 8-2 are not drawn to scale.

In FIG. 8-1, a ring contact surface 834 of a ring 810 of each pad 802 comes into contact with a bottom surface 807 of the substrate 806. In the example shown, the substrate 806 has a concave-up bow. Due to the bow of the substrate 806, only part of the ring contact surface 834 of the left end effector pad 802A and the right end effector pad 802C initially come into contact with the bottom surface 807 of the substrate. In each the left end effector pad 802A and the right end effector pad 802C, the interior part of the ring contact surface 834 is initially in contact with the bottom surface 807 of the substrate. The ring contact surface 834 of the center end effector pad 802B is fully in contact with the bottom surface 807 of the substrate 806.

The weight of the substrate may force the ring 810 down towards the end effector 804 (as can be seen in FIG. 8-1, the pads are tilted slightly inward due to the weight of the substrate resting on their inner most edge portions). As discussed earlier, the force of the substrate may cause the diaphragm to flex and allow the ring contact surface 834 of the left pad 802A and the right pad 802C to flex so as to conform to the localized slope on the bottom surface 807 of the substrate 806. In some examples, the weight of the substrate 806 may force the diaphragm to flex enough allowing each ring contact surface 834 to form a seal to the bottom surface 807 of the substrate. In another example, the force may cause a slight flex of the diaphragm so a substantial portion of the ring contact surface 834 comes in contact with the bottom surface 807 of the substrate 806. In this example, the remaining portion of the ring contact surface 834 may move into a location proximate to the bottom surface 807 of the substrate 806. Vacuum may be applied through a passage of each pad 802. In the pads 802 where a portion of the ring contact surface 834 is not in full contact with the substrate 806, flow resistance from the vacuum may cause a pressure differential. Once a high enough pressure differential develops, the vacuum can suck down the substrate onto the pads 802, forming a seal between the ring contact surface 834 of each pad and the bottom surface 807 of the substrate 806.

Shown in FIG. 8-2 is the substrate 806 in contact with each of the pads 802 when sufficient vacuum is applied. The additional force from the vacuum pushes the substrate 806 further down on each of the pads 802 from the ring 810 of each pad 802 down towards the end effector 804. This additional force may cause the diaphragm to flex so the rings 810 of the pads 802 tilt to match the slope of the substrate in each corresponding localized area. This allows the ring contact surfaces 834 to each make a seal with the bottom surface 807 of the substrate 806. As can be seen in FIG. 8-2, the pads have tilted slightly more so as to align themselves with the slope of the substrate due to the application of the vacuum clamping force.

In some implementations, a controller may be used in a system that incorporates the end effector pads 802 discussed herein. FIGS. 8-1 and 8-2 depict a schematic of an example controller 838 with one or more processors 840 and a memory 842, which may be integrated with electronics for controlling the operation of a vacuum pump 837 to allow the one or more pads 802 to pull vacuum against a substrate 806. The controller 838, depending on the processing requirements and/or the type of system, may be programmed to control any of the processes disclosed herein, such as processes for controlling vacuum pump, as well as other processes or parameters not discussed herein, such as the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a chamber and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example end effector pads according to the present disclosure may be used on wafer handling robots which may be mounted in or part of semiconductor processing tools with a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

Although the foregoing embodiments have been described in some detail for purposes of clarity of understanding, it will be apparent that certain changes and modifications may be practiced within the scope of the appended claims. It should be noted that there are many alternative ways of implementing the system and apparatus of the present embodiments. Accordingly, the present embodiments are to be considered as illustrative and not restrictive, and the embodiments are not to be limited to the details given herein.

1. An end effector pad for supporting a substrate, the end effector pad comprising:
a center portion extending along a longitudinal axis;
a ring extending around, and radially offset from, the center portion;
a diaphragm connecting the ring with the center portion; and
one or more hard-stop structures, wherein:
the diaphragm includes at least three rib regions,
each rib region extends from the center portion to the ring,
a thickness of the diaphragm is thicker in the rib regions than in between the rib regions,
a surface of the ring that is furthest from the center portion and offset from the diaphragm along the longitudinal axis defines a first reference plane that is perpendicular to the longitudinal axis,
one or more hard-stop surfaces of the one or more hard-stop structures that are furthest from the center portion define a second reference plane that is also perpendicular to the longitudinal axis,
the second reference plane is between the diaphragm and the first reference plane, and
the center portion has one or more passages extending therethrough.

2. The end effector pad of claim 1, wherein the center portion, the ring, and the diaphragm form a contiguous structure made of a material having a modulus of elasticity of at least 0.8 GPa.

3. (canceled)

4. The end effector pad of claim 1, wherein regions of the diaphragm between the rib regions have a thickness between 0.003 inches and 0.005 inches.

5. The end effector pad of claim 1, wherein regions of the diaphragm between the rib regions have a thickness between 0.005 inches and 0.007 inches.

6. The end effector pad of claim 1, wherein regions of the diaphragm between the rib regions have a thickness between 0.007 inches and 0.009 inches.

7. The end effector pad of claim 1, wherein, for each rib region:
a surface of that rib region that is closest to the first reference plane defines a third reference plane that is perpendicular to the longitudinal axis, and
the second reference plane is between the third reference plane and the first reference plane.

8. The end effector pad of claim 1, wherein at least a portion of each rib region has a width in a direction transverse to a radial axis perpendicular to the longitudinal axis that is between 0.02 inches and 0.04 inches.

9. The end effector pad of claim 1, wherein the diaphragm has four rib regions.

10. The end effector pad of claim 1, wherein the intersection of the ring and the first reference plane forms a contact region with a radial width that is <5% than a diameter of the ring.

11. The end effector pad of claim 1, wherein the one or more hard-stop surfaces have a radial width that is less than 5% of the maximum dimension of the center portion in a direction perpendicular to the longitudinal axis.

12. (canceled)

13. (canceled)

14. The end effector pad of claim 1, wherein the one or more hard-stop structures comprises a plurality of arcuate wall segments arranged in a circular array around a center axis of the center portion.

15. The end effector pad of claim 14, wherein:
the diaphragm includes at least three rib regions in which the thickness of the diaphragm is thicker than in regions of the diaphragm in between the rib regions, each rib region extending from the center portion to the ring, and
each arcuate wall segment is positioned at an interior end of a corresponding one of the rib regions.

16. The end effector pad of claim 1, wherein at least a portion of the passage has a hexagonal cross-sectional shape.

17. The end effector pad of claim 16, wherein each corner of the hexagonal cross-sectional shape has an arcuate notch.

18. The end effector pad of claim 1, wherein at least a portion of an exterior surface of the center portion is threaded.

19. The end effector pad of claim 1, wherein the end effector pad is made of plastic.

20. The end effector pad of claim 19, wherein the plastic is a conductive electrostatic discharge-rated plastic, a polybenzimidazole (PBI), or a carbon-filled polyetheretherketone (PEEK).

21. (canceled)

22. (canceled)

23. The end effector pad of claim 1, wherein the ring has a diameter between 0.20 inches and 1.50 inches.

24. (canceled)

25. A kit for use on a wafer handling robot, the kit comprising at least three of the end effector pads of claim 1.

26. (canceled)

27. The kit of claim 25, further comprising a hex wrench configured to fit in the portion of the passage with the hexagonal cross-sectional shape.
